(19) United States
(12) Patent Application Publication
(10) Pub. No.: US 2025/0089885 A1
(43) Pub. Date: Mar. 20, 2025

(54) BRUSH ROLLER STRUCTURE

(71) Applicant: CENEFOM CORP., Miaoli County (TW)

(72) Inventor: Chen-Ping HSU, Miaoli County (TW)

(21) Appl. No.: 18/732,640

(22) Filed: Jun. 4, 2024

(30) Foreign Application Priority Data
Sep. 15, 2023 (TW) 112135351

(51) Int. Cl. A46B 11/00; A46B 9/00; A46B 13/00

(52) U.S. Cl. CPC A46B 11/0072; A46B 9/005; A46B 13/001; A46B 2200/3086

(57) ABSTRACT

A brush roller structure includes a foam body, a central channel, a microporous area, and through holes. The foam body comprises flow channels formed by interlaced pores, and the pores have an average pore diameter ranging from 300 μm to 500 μm. The central channel is arranged in the foam body and communicates with the flow channels. The microporous area is located on the surface of the foam body, and has micro pores, and the diameter of the micro pores is smaller than the average diameter of the pores in the foam body. The through holes are arranged on the outer surface of the foam body, wherein the depth of the through holes is between 50 μm and 300 μm, and the ratio of the total area of the through holes to the outer surface of the foam body is between 10% and 90%.

### CROSS-REFERENCE TO RELATED APPLICATION

This application claims priority to Taiwan Application Serial Number 112135351, filed Sep. 15, 2023, which is herein incorporated by reference in its entirety.

### BACKGROUND

### Field of Invention

The present disclosure relates to a brush roller structure, and more particularly to a brush roller structure that has high fluid flux and uniformity and can adjust the flow of fluid in the radial direction.

### Description of Related Art

In a modern society with booming information development, the related electronics industry is also developing rapidly, and the semiconductor manufacturing process is an indispensable role to support the electronics industry.

In the semiconductor manufacturing process, chemical mechanical polishing (CMP) can achieve a global planarization for the surface of precision components such as semiconductor wafers. However, during the chemical mechanical polishing process, it is easy to cause damage to the wafer surface. Defects that produce organic residues, micro particles and corrosion phenomena require the wafer to be cleaned after finishing the chemical mechanical polishing to facilitate subsequent processes and improve the wafer quality.

In the process of cleaning the wafer, water and cleaning fluid are both used with cleaning rollers to remove foreign matter on the wafer surface by the relative movement of water, cleaning fluid, and cleaning rollers. On the premise of not scratching the wafer surface, the part where the cleaning roller contacts the wafer surface must use a brush roller made of soft foam material. In order to achieve sufficient cleaning effect, the cleaning roller must also have a hard core structure to withstand the pressure, water pressure and rotational speed exerted on the cleaning roller at a certain intensity without causing the cleaning roller to deform. The cleaning roller is usually located at the water outlet, and the flow channel in the hard core of the cleaning roller is usually used to control the amount of water required to reach each contact point between the cleaning roller and the wafer. However, when water passes through the foam brush roller in the cleaning roller, the pore diameter and pore distribution pattern inside the foam brush roller will affect the flux and flow direction of the water, making it impossible to flow out smoothly from the surface of the foam brush roller. Overflow loss causes the effective water output rate to be too low or inconsistent with the water output at each contact point of the wafer, making it impossible to meet the requirements of the cleaning process.

Therefore, how to provide a brush roller structure that can regulate the amount and uniformity of water output in the radial direction and reduce the consumption of cleaning liquids to improve the efficiency of wafer cleaning has become a development goal for those skilled in the art.

### SUMMARY

In one or more embodiments, a brush roller structure includes: a foam body including a plurality of flow channels formed by interlaced pores, and the pores have an average pore diameter ranging from 300 μm to 500 μm; a central channel disposed in the foam body and fluidly-communicable with the flow channels; a microporous area disposed on a surface layer of the foam body, wherein the microporous area has a plurality of micropores, and the micropores have an average pore diameter smaller than the average pore diameter of the pores of the foam body; and a plurality of through holes disposed on an outer surface of the foam body, wherein the through holes have a depth ranging from 50 μm to 300 μm, and a total area of all the through holes occupies 10% to 90% of the outer surface of the foam body.

In one or more embodiments, the micropores in the microporous area have an average pore diameter ranging from 1 μm to 100 μm.

In one or more embodiments, the microporous area has a thickness ranging from 30 μm to 200 μm.

In one or more embodiments, the depth of the through holes is greater than a thickness of the microporous area.

In one or more embodiments, the through holes are continuous or discontinuous circles, ovals, strips or combinations thereof, or areas formed by combinations thereof, and the through holes are evenly distributed on the outer surface of the foam body or gathered into areas on the outer surface of the foam body.

In one or more embodiments, the total area of the through holes occupies 20% to 70% of the outer surface of the foam body.

In one or more embodiments, the foam body has a porosity ranging from 70% to 95%.

In one or more embodiments, the central channel has a width ranging from 9 mm to 30 mm.

In one or more embodiments, the outer surface of the foam further includes at least one bump.

In one or more embodiments, the bump has a bottom width ranging from 7 mm to 13 mm and a top width ranging from 6 mm to 11 mm.

In one or more embodiments, the bump has a height ranging from 4 mm to 6 mm.

In one or more embodiments, the foam body is made from polyvinyl alcohol cross-linked compound.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1a illustrate a perspective view of a brush roller structure according to one embodiment of the present disclosure;

FIG. 1b illustrates a cross-sectional view of a surface layer of a brush roller structure according to one embodiment of the present disclosure;

FIG. 2 illustrates a perspective view of a brush roller structure according to another embodiment of the present disclosure;

FIG. 3 illustrates a 60 magnification electron microscope image showing a foam surface and a surface layer of a brush roller structure of the present disclosure;

FIG. 4a illustrates a 60 magnification electron microscope image showing a surface through hole pattern of a brush roller structure according to one embodiment of the present disclosure; and

FIG. 4b illustrates a 60 magnification electron microscope image showing a surface through hole pattern of a brush roller structure according to another embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The embodiments of the cleaning roller central shaft of the present invention will be described below with reference to the relevant drawings. To facilitate understanding, the same components in the following embodiments are labeled with the same symbols.

The “average pore diameter” in this disclosure is expressed by the pore size range that accounts for 50% of the middle value in the pore size-number distribution. The pore size-number distribution is based on cutting the foam body into 1-inch test pieces. The size and number of each pore are measured with an electron microscope according to the ASTM-D3576 method, and then calculated to obtain the average pore diameter.

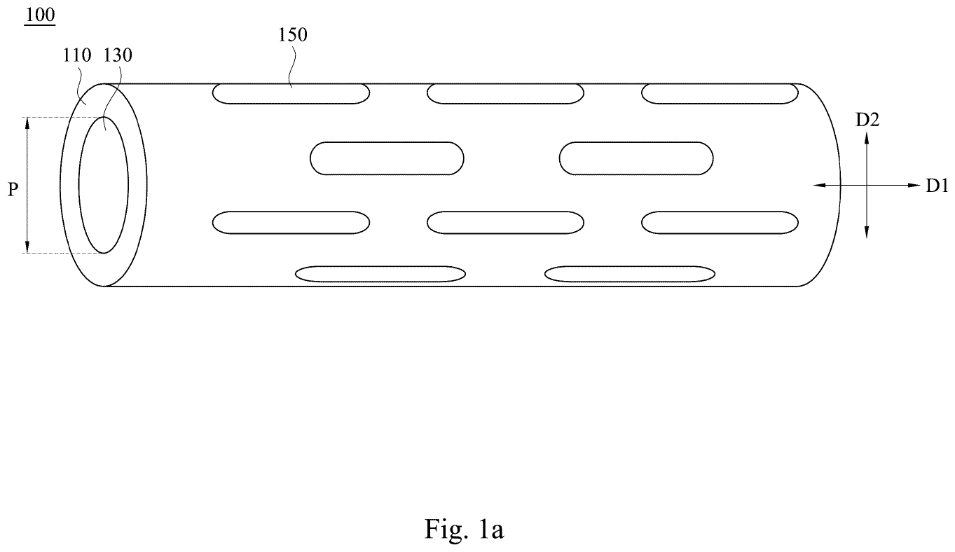

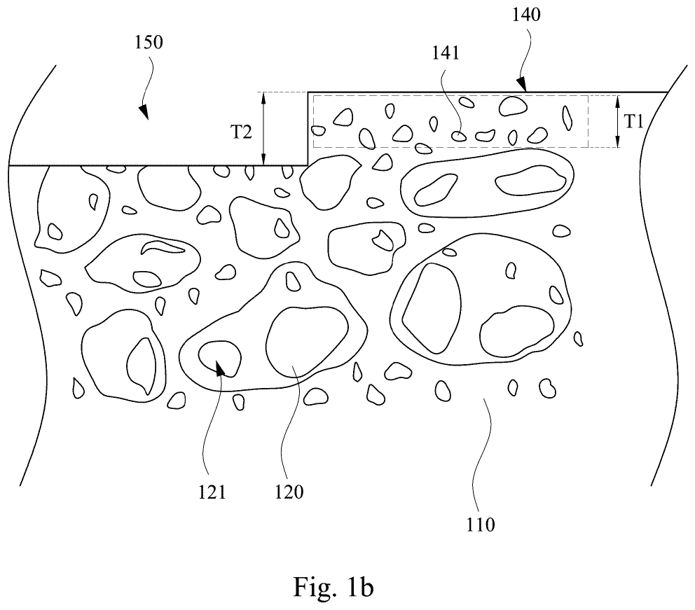

FIGS. 1a and 1b respectively illustrate a perspective view of a brush roller structure 100 and a cross-sectional view of a surface layer thereof along a thickness direction according to one embodiment of the present disclosure. The brush roller structure 100 includes a foam body 110 that has a plurality of flow channels 121 formed by a plurality of pores 120 interlaced with each other. An average pore diameter of the pores 120 is between 300 μm and 500 μm. A central channel 130 is provided in the foam body 110 and fluidly-communicable with the flow channels 121. A microporous area 140 is located on a surface layer of the foam body 110. The microporous area 140 has a plurality of micropores 141, and an average pore diameter of the micropores 141 is smaller than the average pore diameter of the pores 120 of the foam body 110. A plurality of through holes 150 are provided on an outer surface of the foam body 110, wherein a depth T2 of the through holes 150 is between 50 μm and 300 μm, and a total area of the through holes 150 accounts for 10% to 90% of the total outer surface area of the foam body 110, and the through holes 150 are fluidly-communicable with the flow channels 121.

When the brush roller structure 100 of the present invention is used to clean wafers or other objects to be cleaned, the brush roller structure 100 is sleeved on a brush roller core (not illustrated) with a central channel 130, and the cleaning liquid is flown from the brush roller core and dispersed into the brush roller structure 100. Since the flow channel 121 is formed by a plurality of pores 120 with an average pore diameter ranging from 300 μm to 500 μm, the flow channel 121 formed by the pores within such average pore diameter range can maintain a certain liquid flux such that the amount of liquid input will not be affected. When the amount of liquid input is much higher than the amount of liquid that the brush roller structure 100 can output, it will result in overflow loss. Because the surface layer of the foam body 110 has microporous areas 140, the liquid will not be directly flown out in large amounts to the outer surface of the foam body 110 along the radial direction D2 of the brush roller structure 100, but can be quickly transferred to the brush roller structure 100 along the axial direction DI and the radial direction D2 through the central channel 130 evenly and with low resistance, and then guided out through the plurality of through holes 150 for wafers and other surface cleaning.

Furthermore, the total area of the through holes 150 accounts for between 10% and 90% of the total outer surface area of the foam body 110, preferably between 20% and 70% of the total outer surface area of the foam body 110. For cleaning equipment with different water outputs and/or objects to be cleaned with different cleaning water pressure requirements, the brush roller structure 100 with an appropriate total area ratio of the through holes 150 can be selected to achieve optimal cleaning efficiency and cleanliness.

According to an embodiment of the brush roller structure of the present invention, the pore diameter of the micropores 141 in the microporous area 140 is between 1 μm and 100 μm. Because the pore diameter of the micropores 141 is smaller than the average diameter of the pores 120 of the foam body 110, the flow rate and flow speed of the cleaning liquid passing through the microporous area 140 are both lower than the flow channel 121 in the foam body 110, so the foam body 110 is easier to reach the state of being filled with cleaning liquid. Furthermore, the microporous area 140 is located on the surface layer of the foam body 110 and has a thickness T1 of 30 μm to 200 μm. The depth T2 of the through holes 150 located on the outer surface of the foam body 110 is greater than the thickness T1 of the microporous area 140 such that the cleaning liquid can be smoothly discharged from the foam body 110.

According to one embodiment of the brush roller structure of the present invention, the shape, number and position of the through holes 150 on the outer surface of the foam body 110 are not limited. For example, the through holes 150 can be evenly dispersed or non-equidistantly distributed according to the strength of the water pressure, as long as the cleaning liquid entering the brush roller structure 100 can be smoothly exported and evenly flushed everywhere on the surface of the object to be cleaned, e.g., a wafer. The through holes 150 on the outer surface of the foam body 110 may form circles, ovals, strips or combinations thereof. According to an embodiment of the brush roller structure of the present invention, the through holes can be continuous or discontinuous circles, ovals, strips, or combinations thereof, or areas formed by combinations thereof, and the through holes 150 can be evenly distributed on the outer surface of the foam body or gathered into areas on the outer surface of the foam body.

According to one embodiment of the brush roller structure of the present invention, the porosity of the foam body 110 is between 70% and 95%. A suitable porosity can increase the amount of cleaning liquid that the brush roller structure 100 can contain, and has appropriate softness and sufficient resilience as well to effectively clean wafers or other precision components without damaging their surfaces.

According to one embodiment of the brush roller structure of the present invention, a width P of the central channel 130 is between 9 mm and 30 mm.

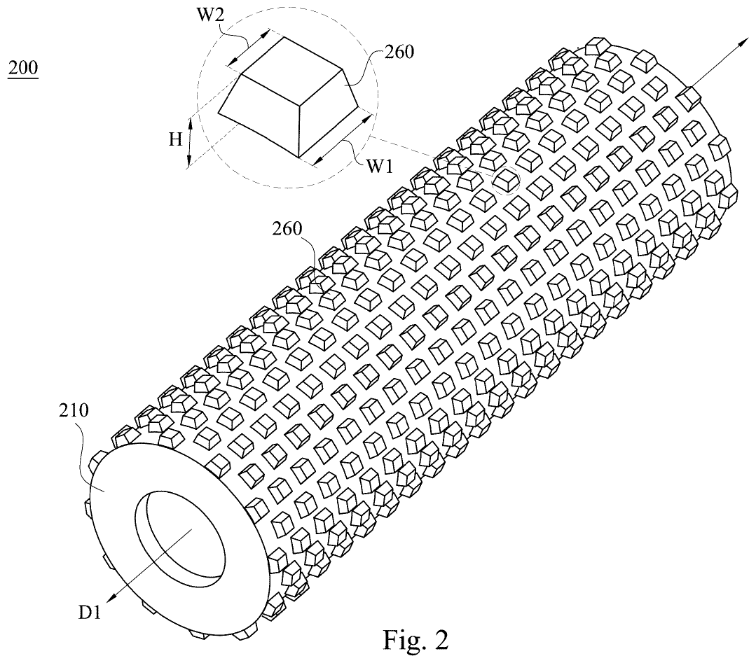

According to another embodiment of the brush roller structure of the present invention, the outer surface of the foam body of the brush roller structure may further include at least one bump. These bumps may be frustum or cylinders protruding from the outer surface of the foam body. The top shapes of the bumps include but are not limited to circles or rectangles, and the side shapes of the bumps include but are not limited to rectangles or trapezoids. FIG. 2 is a perspective view of a brush roller structure according to another embodiment of the present disclosure, in which the outer surface of the foam body 210 of the brush roller structure 200 further includes a plurality of columnar bumps 260. In one embodiment of the brush roller structure of the present invention, a height H of the bump 260 is between 4 mm and 6 mm, a bottom width W1 of the bump 260 is between 7 mm and 13 mm, and a top width W2 of the bump 260 is between 6 mm and 11 mm to provide sufficient lateral support and better cleaning power when the bumps 260 are into contact with the object to be cleaned.

The brush roller structure of the present invention may be a foam of polyvinyl alcohol cross-linked compound. The material of the brush roller structure can be obtained by foaming a reaction solution made of PVA or other foaming materials. In an embodiment, the foaming material, cross-linking agent, catalyst and solvent can be uniformly mixed to form a reaction solution, and then filled with gas with a volume percentage of 21% to 50% relative to the reaction solution. The reaction solution with mixed and dispersed gas are then poured into the mold, and the appropriate aging temperature is adjusted to control the pore formation speed and distribution, and then mold it to obtain a foam body with a porosity between 70% and 95% suitable for the present invention.

According to one embodiment of the brush roller structure of the present invention, the cross-linking agent used in the foam can be selected from groups formed of formaldehyde, acetaldehyde, glyoxal, propionaldehyde, butyraldehyde, succinic aldehyde and glutaraldehyde. The solvent can be one that makes PVA and the like easy to dissolve and disperse, such as water. The filled gas can be air, or low-activity gases such as nitrogen and helium can be used to form bubbles in the foaming materials when they are mixed to form a reaction solution without chemically reacting with other components. This can achieve the effect of conventionally difficult to control the pore size and distribution position with solid pore-forming agents. It can also prevent the problems of incompletely dissolved and removed solid pore-forming agents from affecting the cleaning liquid flux in the brush roller structure and remaining in the brush roller structure and on the surface to be cleaned.

According to one embodiment of the brush roller structure of the present invention, the catalyst can be selected from the group consisting of hydrochloric acid, sulfuric acid, phosphoric acid and nitric acid.

According to one embodiment of the brush roller structure of the present invention, the reaction solution forming the foam may further include a surfactant to maintain the bubble content in the reaction solution and prevent the bubbles from collapsing during the manufacturing process. Suitable surfactants may be diglycerol polypropylene glycol ether, polyoxyethylene stearate, polyethylene glycol octylphenyl ether or sodium alkyl benzene sulfonate.

Methods for forming the through holes on the outer surface of the foamed body of the brush roller structure of the present invention include laser elimination, knife scraping, chemical etching or grinding, etc. In one embodiment, laser can be used to eliminate through holes with a certain depth in the microporous area and reduce damage and residues to the internal pores and flow channel structures. In one embodiment of the brush roller structure of the present invention, a minimum width of each through hole is greater than 50 μm and preferably not greater than 450 μm, and the depth of each through hole is greater than the thickness of the microporous area to increase the flow conduction effect. Furthermore, the laser elimination method can form through holes of various shapes on the outer surface of the brush roller structure and/or areas where the through holes of various shapes are gathered. For example, a single point laser method can be used to generate dot-shaped through holes. Or use a single-point laser method with the laser elimination direction and frequency to form a continuous or discontinuous circles, ovals, strips or combination thereof, or an area formed by a combination of through holes, and its etc. are uniformly distributed on the outer surface of the foam body or gathered into regions and distributed on the outer surface of the foam body.

In the embodiment of the present invention, the brush roller structure includes a bump structure, the laser elimination method is used to form a through hole that is not affected by the ups and downs of the outer surface of the foam. The microporous areas over a top, sides or bottom of the bump structure on the outer surface of the foam can be eliminated to facilitate the distribution of through holes on the outer surface of the foam and enhance the flow diversion effect. A power of the laser elimination method suitable for the brush roller structure of the present invention can be less than 80W, and the wavelength of the laser light in the laser elimination method can be 8000 nm to 12000 nm, or 800 nm to 1200 nm.

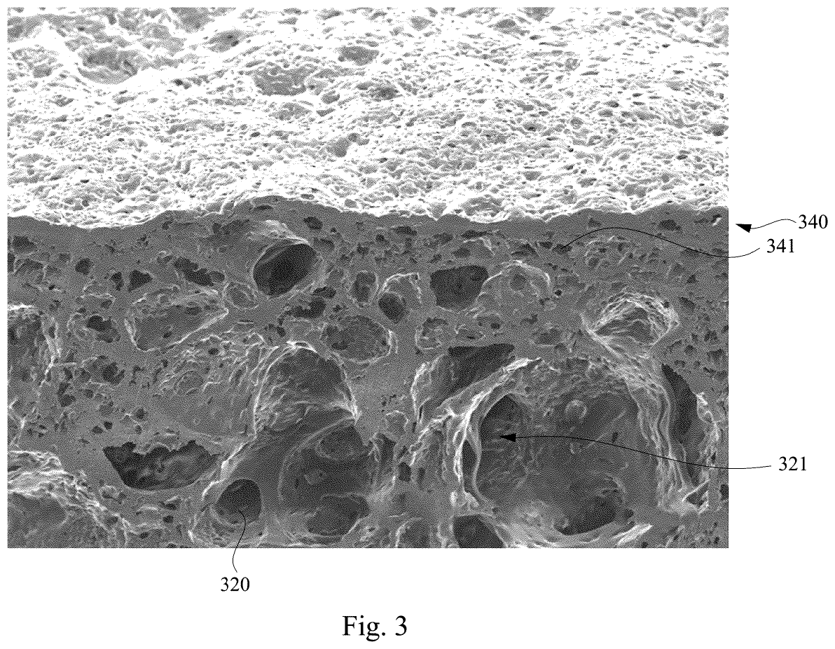

The brush roller structure of the present invention has excellent fluid penetrability, which is conducive to the passage of cleaning liquid and effectively clean wafers or other precision components, and avoids excessive overflow and loss in high water volume cleaning processes due to flow channel resistance. FIG. 3 illustrates a 60-magnification electron microscope image of a partial cross-section of the foam surface and surface layer of the brush roller structure of the present invention. Since the surface layer of the foam body in the brush roller structure has a certain thickness of the microporous area 340, and the pore diameters of the micropores 341 in the microporous area 340 are much smaller than the average pore diameter of the foam pores 320 or the flow channels 321. Therefore, the input cleaning liquid is not easy to flow out of the outer surface in large volume directly through the radial direction of the brush roller structure, but can be quickly transferred to all parts of the brush roller structure along the axial and radial directions evenly and with low resistance.

Furthermore, the brush roller structure foam of the present invention has a porosity ranging from 70% to 95% and the average pore diameter ranges from 300 μm to 500 μm, which can provide a compressive stress of greater than or equal to 60 g/cm² to less than or equal to 100 g/cm² to suit the application of cleaning wafers or other precision components. When the compressive stress of the brush roller structure is higher than a lower limit, the resilience can make the brushing efficiency meet expectations, and when the compressive stress of the brush roller structure is lower than an upper limit under the predetermined compression ratio, it can avoid the object to be cleaned from being damaged due to excessive stress during the scrubbing process.

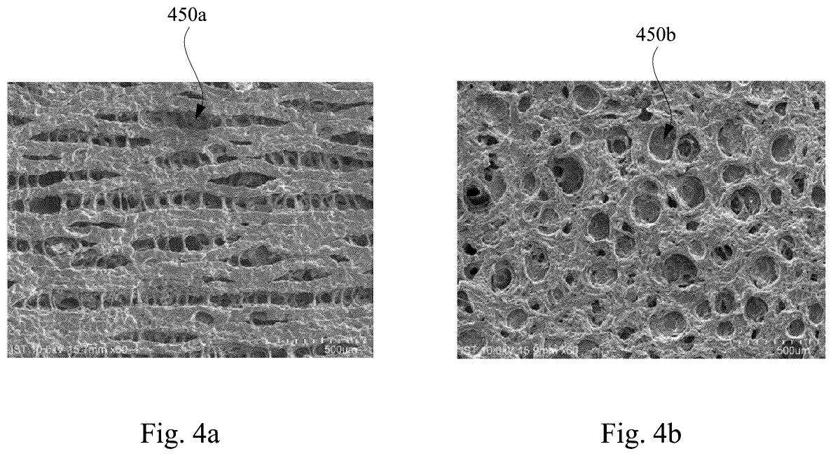

FIGS. 4a and 4b illustrates 60-magnification electron microscope images of the surface the brush roller structure according to two different embodiments of the present invention. FIG. 4a shows through holes 450a arranged in a long strip area formed on the surface of the brush roller structure. FIG. 4b shows through holes 450b formed in dot shapes on the surface of the brush roller structure. However, the through holes of the brush roller structure of the present invention are not limited by these two embodiments. In other brush roller structure implementations, the through hole can also be a region formed by a combination of a circle, oval and strip shape. The brush roller structure of the present invention can provide local water flow direction, pressure fine adjustment, etc. through the different shape areas and arrangement distribution of the surface through holes, and can be applied to various precision components to achieve a better cleaning state.

In sum, the brush roller structure disclosed herein helps to increase the penetration rate of fluid through the interior of the foam body, and is beneficial to regulate the flow rate and flow speed of fluid flowing through the brush roller structure, and can be used for different types of objects to be cleaned, which not only helps to improve the efficiency of the cleaning process, but also reduces the use of chemicals for cleaning and the waste of water resources. Therefore, the brush roller structure of the present invention can be applied to the cleaning process of the electronics industry, and has application potential in related markets.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A brush roller structure comprising:
a foam body comprising a plurality of flow channels formed by a plurality of pores interlaced with each other, and the pores have an average pore diameter ranging from 300 μm to 500 μm;
a central channel disposed in the foam body and fluidly-communicable with the flow channels;
a microporous area disposed on a surface layer of the foam body, wherein the microporous area has a plurality of micropores, and the micropores have an average pore diameter smaller than the average pore diameter of the pores of the foam body; and
a plurality of through holes disposed on an outer surface of the foam body,
wherein the through holes have a depth ranging from 50 μm to 300 μm, and a total area of the through holes occupies 10% to 90% of the outer surface of the foam body.

2. The brush roller structure of claim 1, wherein the micropores in the microporous area have an average pore diameter ranging from 1 μm to 100 μm.

3. The brush roller structure of claim 1, wherein the microporous area has a thickness ranging from 30 μm to 200 μm.

4. The brush roller structure of claim 1, wherein the depth of the through holes is greater than a thickness of the microporous area.

5. The brush roller structure of claim 1, wherein the through holes are continuous or discontinuous circles, ovals, strips or combinations thereof, or areas formed by combinations thereof, and the through holes are evenly distributed on the outer surface of the foam body or gathered into areas on the outer surface of the foam body.

6. The brush roller structure of claim 1, wherein the total area of the through holes occupies 20% to 70% of the outer surface of the foam body.

7. The brush roller structure of claim 1, wherein the foam body has a porosity ranging from 70% to 95%.

8. The brush roller structure of claim 1, wherein the central channel has a width ranging from 9 mm to 30 mm.

9. The brush roller structure of claim 1, wherein the outer surface of the foam body further includes at least one bump.

10. The brush roller structure of claim 9, wherein the bump has a bottom width ranging from 7 mm to 13 mm and a top width ranging from 6 mm to 11 mm.

11. The brush roller structure of claim 9, wherein the bump has a height ranging from 4 mm to 6 mm.

12. The brush roller structure of claim 1, wherein the foam body is made from polyvinyl alcohol cross-linked compound.
